(19) United States
(12) Patent Application Publication
(10) Pub. No.: US 2018/0226508 A1
(43) Pub. Date: Aug. 9, 2018

(54) TFT BACKPLANE AND MANUFACTURING METHOD THEREOF

(71) Applicant: Wuhan China Star Optoelectronics Technology Co., Ltd., Wuhan City (CN)

(72) Inventor: Zhe Chen, Wuhan City (CN)

(21) Appl. No.: 15/505,110

(22) PCT Filed: Dec. 28, 2016
(86) PCT No.: PCT/CN2016/112525

§ 371 Date: Feb. 20, 2017

(30) Foreign Application Priority Data
Dec. 13, 2016 (CN) 201611147758.3

(51) Int. Cl. H01L 29/786; H01L 29/66; H01L 27/12; H01L 27/32

(52) U.S. Cl. CPC H01L 29/7869; H01L 29/66969; H01L 29/66765; H01L 27/3274; H01L 27/1214; H01L 27/3262; H01L 29/78603

(57) ABSTRACT

The present invention provides a TFT backplane and a manufacturing method thereof. The manufacturing method of the TFT backplane according to the present invention uses a half tone mask that has three light transmission rates to subject an organic photoresist layer to a photolithographic process so that three exposure effects can be achieved with one photolithographic process to thereby simultaneously form a pixel definition layer, an opening in the pixel definition layer, and a support layer. Compared to the known techniques, the present invention may save one mask and one round of photolithographic operation and thus may effectively reduce fixture costs and manufacturing costs. Further, structurally, the support layer and the pixel definition layer are a unitary structure so as to prevent detachment of the support layer and thus effectively improving displaying quality of a display device. The TFT backplane according to the present invention is such that a pixel definition layer and a support layer are formed in the same process so that the manufacturing process is simple and the manufacturing cost is low and since the pixel definition layer and the support layer are of a unitary structure, an issue of detachment of the support layer can be eliminated thereby effectively improving displaying quality of a display device.

### BACKGROUND OF THE INVENTION

### 1. Field of the Invention

The present invention relates to the field of display technology, and more particular to a thin-film transistor (TFT) backplane and a manufacturing method thereof.

### 2. The Related Arts

Organic light-emitting diode (OLED) displays, which are also known as organic electroluminescent displays, are a newly emerging flat panel display device and possess advantages, such as simple manufacturing operation, low costs, reduced power consumption, high luminous brightness, wide range of operation temperature, compact size, fast response, easy realization of color displaying and large-screen displaying, easy realization of matching with integrated circuit (IC) driver, and easy realization of flexible displaying, and show future prosperity of wide applications.

An OLED is generally made up of a substrate, an anode arranged on the substrate, a hole injection layer arranged on the anode, a hole transport layer arranged on the hole injection layer, an emissive layer arranged on the hole transport layer, an electron transport layer arranged on the emissive layer, an electron injection layer arranged on the electron transport layer, and a cathode arranged on the electron injection layer. The principle of light emission of an OLED display device is that when a semiconductor material and an organic light emission material are driven by an electric field, carrier currents are injected and re-combine to cause emission of light. Specifically, the OLED often uses an indium tin oxide (ITO) electrode and a metal electrode to respectively serve as the anode and cathode of the device and electrons and holes, when driven by a predetermined electrical voltage, are respectively injected into the electron transport layer and the hole transport layer from the cathode and the anode such that the electrons and the holes respectively migrate through the electron transport layer and the hole transport layer to get into the emissive layer and meet in the emissive layer to form excitons that excites light emissive molecules, the later undergoing radiation relaxation to give off visible light.

Based on the way of driving, OLEDs can be classified in two categories, passive matrix OLED (PMOLED) and active matrix OLED (AMOLED), in which PMOLED emits light when data are written in and does not emit light when data are not written in. Such a driving method involves a simple structure, has a low cost, and is easy to design, making it generally applied to medium- and small-sized display devices. A major difference of an AMOLED from a PMOLED is that each pixel comprises a capacitor for storage of data so as to keep each pixel in a light emitting condition. Since the power consumption of the AMOLED is apparently smaller than that of the PMOLED, together with the driving method thereof being applicable to large-sized and high-definition display devices that are under development, the AMOLED is becoming the primary orientation of further development. Mainstream techniques that are commonly acknowledged as being applicable to driving AMOLED backplanes are two: oxide thin-film transistor (TFT) backplanes and low temperature poly-silicon TFT backplanes. A major difference between the two backplane techniques is the difference in the design and structure of TFTs, where the low temperature poly-silicon TFT requires more operation steps and thus a complicated process, so that the oxide TFT backplane is the contemporary primary orientation of development.

FIG. 1 is a schematic view illustrating the structure of a conventional oxide TFT backplane. As shown in FIG. 1, the oxide TFT backplane comprises, sequentially stacked from bottom to top, a backing plate 100, a gate electrode 110, a gate insulation layer 200, an oxide semiconductor layer 300, an etching stopper layer 400, a source electrode 510 and a drain electrode 520, a passivation layer 450, a planarization layer 500, an anode 600, a pixel definition layer 800, and a support layer 900, wherein the support layer 900 comprises a plurality of support members 910 that are spaced from each other and the support members 910 have a predetermined height.

In a manufacturing process of the above oxide TFT backplane, the pixel definition layer 800 and the support layer 900 each require the use of a mask plate and are each formed through a photolithographic operation. Thus, the manufacturing cost is high and the manufacturing time is long. Further, since the support layer 900 and the pixel definition layer 800 are manufactured separately, adhesion between the support layer 900 and the pixel definition layer 800 is relatively poor such that the support layer 900 may get readily damaged and detached in a subsequent process. This is adverse to the protection of the support layer 900 and also causes deterioration of the displaying quality of the display due to the detached support layer 900 falling into the display zone.

### SUMMARY OF THE INVENTION

Objectives of the present invention are to provide a manufacturing method of a thin-film transistor (TFT) backplane, which helps save costs of fixtures and costs of manufacturing and also prevents detachment of a support layer to effectively improve displaying quality of a display device.

The objectives of the present invention are also to provide a TFT backplane, which can be manufactured with a simple process with a low manufacturing cost, and can prevent detachment of a support layer so as to effectively improve displaying quality of a display device.

To achieve the above obj ectives, the present invention provides a manufacturing method of a TFT backplane, which comprises the following steps:

Step 1: providing a backing plate, forming a gate electrode on the backing plate, and forming a gate insulation layer on the gate electrode and the backing plate;

Step 2: forming an active layer on the gate insulation layer and located above and corresponding to the gate electrode, forming an etching stopper layer on the active layer and the gate insulation layer, and forming a first via and a second via in the etching stopper layer to respectively correspond to two ends of the active layer; and

forming a source electrode and a drain electrode on the etching stopper layer, such that the source electrode and the drain electrode are respectively in contact engagement with the two ends of the active layer through the first via and the second via;

Step 3: forming a passivation layer on the source electrode, the drain electrode, and the etching stopper layer and forming a planarization layer on the passivation layer;

forming a third via in the passivation layer and the planarization layer to be located above and corresponding to the drain electrode; and

forming an anode on the planarization layer, such that the anode is in contact engagement with the drain electrode through the third via; and

Step 4: forming an organic photoresist layer on the anode and the planarization layer and using a half tone mask to subject the organic photoresist layer to exposure and development so as to simultaneously form a pixel definition layer and a support layer located on the pixel definition layer, wherein the pixel definition layer comprises an opening formed therein to be located above and corresponding to the anode and the support layer comprises a plurality of support members that are spaced from each other.

In Step 4, the half tone mask comprises a full transmission area corresponding to the opening, a non-transmitting area corresponding to the support layer, and a partial transmission area corresponding to a portion of the pixel definition layer other than the opening and an area covered by the support layer.

The full transmission area has a light transmission rate of 100%; the partial transmission area has a light transmission rate of 50%; and the non-transmission area has a light transmission rate of 0%.

The active layer is formed of a material comprising an oxide semiconductor.

The oxide semiconductor comprises indium gallium zinc oxide.

The support members have a configuration of a pillar shape.

The present invention also provides a TFT backplane, which comprises: a backing plate, a gate electrode arranged on the backing plate, a gate insulation layer arranged on the gate electrode and the backing plate, an active layer arranged on the gate insulation layer and located above and corresponding to the gate electrode, an etching stopper layer arranged on the active layer and the gate insulation layer, a source electrode and a drain electrode arranged on the etching stopper layer, a passivation layer arranged on the source electrode, the drain electrode, and the etching stopper layer, a planarization layer arranged on the passivation layer, an anode arranged on the planarization layer, a pixel definition layer arranged on the anode and the planarization layer, and a support layer arranged on the pixel definition layer;

wherein the etching stopper layer comprises a first via and a second via formed therein to respectively correspond to two ends of the active layer and the source electrode and the drain electrode are respectively in contact engagement with the two ends of the active layer through the first via and the second via;

the passivation layer and the planarization layer comprise a third via formed therein to correspond to the drain electrode and the anode is in contact engagement with the drain electrode through the third via;

the pixel definition layer comprises an opening formed therein and located above and corresponding to the anode and the support layer comprises a plurality of support members that are spaced from each other; and

the pixel definition layer and the support layer are of a unitary structure and are formed of the same material.

The active layer is formed of a material comprising an oxide semiconductor.

The oxide semiconductor comprises indium gallium zinc oxide.

The support members have a configuration of a pillar shape.

The present invention further provides a manufacturing method of a TFT backplane, which comprises the following steps:

Step 1: providing a backing plate, forming a gate electrode on the backing plate, and forming a gate insulation layer on the gate electrode and the backing plate;

Step 2: forming an active layer on the gate insulation layer and located above and corresponding to the gate electrode, forming an etching stopper layer on the active layer and the gate insulation layer, and forming a first via and a second via in the etching stopper layer to respectively correspond to two ends of the active layer; and

forming a source electrode and a drain electrode on the etching stopper layer, such that the source electrode and the drain electrode are respectively in contact engagement with the two ends of the active layer through the first via and the second via;

Step 3: forming a passivation layer on the source electrode, the drain electrode, and the etching stopper layer and forming a planarization layer on the passivation layer;

forming a third via in the passivation layer and the planarization layer to be located above and corresponding to the drain electrode; and

forming an anode on the planarization layer, such that the anode is in contact engagement with the drain electrode through the third via; and

Step 4: forming an organic photoresist layer on the anode and the planarization layer and using a half tone mask to subject the organic photoresist layer to exposure and development so as to simultaneously form a pixel definition layer and a support layer located on the pixel definition layer, wherein the pixel definition layer comprises an opening formed therein to be located above and corresponding to the anode and the support layer comprises a plurality of support members that are spaced from each other;

wherein the active layer is formed of a material comprising an oxide semiconductor; and

wherein the support members have a configuration of a pillar shape.

The efficacy of the present invention is that the present invention provides a manufacturing method of a TFT backplane, which uses a half tone mask that has three light transmission rates to subject an organic photoresist layer to a photolithographic process so that three exposure effects can be achieved with one photolithographic process to thereby simultaneously form a pixel definition layer, an opening in the pixel definition layer, and a support layer. Compared to the known techniques, the present invention may save one mask and one round of photolithographic operation and thus may effectively reduce fixture costs and manufacturing costs. Further, structurally, the support layer and the pixel definition layer are a unitary structure so as to prevent detachment of the support layer and thus effectively improving displaying quality of a display device. The present invention provides a TFT backplane in which a pixel definition layer and a support layer are formed in the same process so that the manufacturing process is simple and the manufacturing cost is low and since the pixel definition layer and the support layer are of a unitary structure, an issue of detachment of the support layer can be eliminated thereby effectively improving displaying quality of a display device.

For better understanding of the features and technical contents of the present invention, reference will be made to the following detailed description of the present invention and the attached drawings. However, the drawings are provided only for reference and illustration and are not intended to limit the present invention.

### BRIEF DESCRIPTION OF THE DRAWINGS

The technical solution, as well as other beneficial advantages, of the present invention will become apparent from the following detailed description of embodiments of the present invention, with reference to the attached drawings.

In the drawings:

FIG. 1 is a schematic view illustrating the structure of a conventional oxide thin-film transistor (TFT) backplane;

FIG. 2 is a flow chart illustrating a manufacturing method of a TFT backplane according to the present invention;

FIG. 3 is a schematic view illustrating Step 1 of the manufacturing method of the TFT backplane according to the present invention;

FIG. 4 is a schematic view illustrating Step 2 of the manufacturing method of the TFT backplane according to the present invention;

FIG. 5 is a schematic view illustrating Step 3 of the manufacturing method of the TFT backplane according to the present invention;

FIGS. 6-7 are schematic views illustrating Step 4 of the manufacturing method of the TFT backplane according to the present invention; and

FIG. 8 is a schematic view illustrating the structure of a TFT backplane according to the present invention.

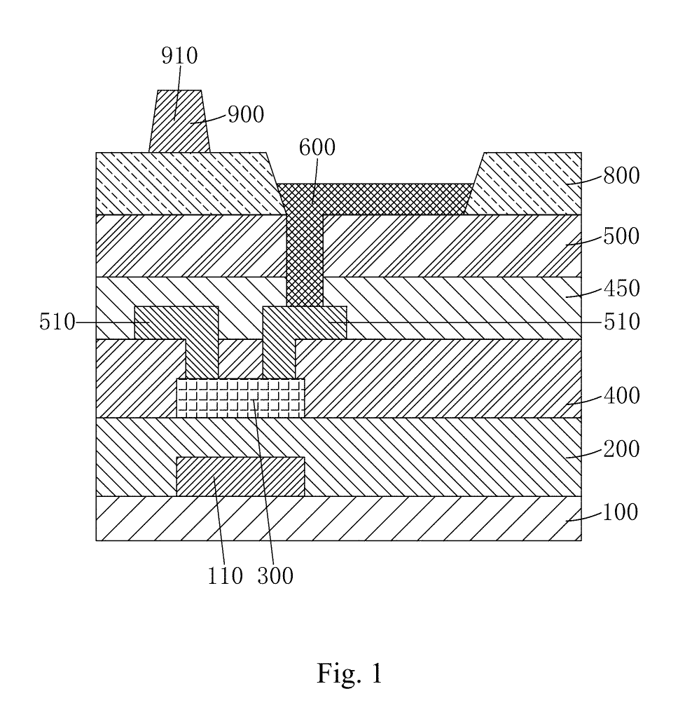

### DETAILED DESCRIPTOIN OF THE PREFERRED EMBODIMENTS

To further expound the technical solution adopted in the present invention and the advantages thereof, a detailed description will be given with reference to the preferred embodiments of the present invention and the drawings thereof.

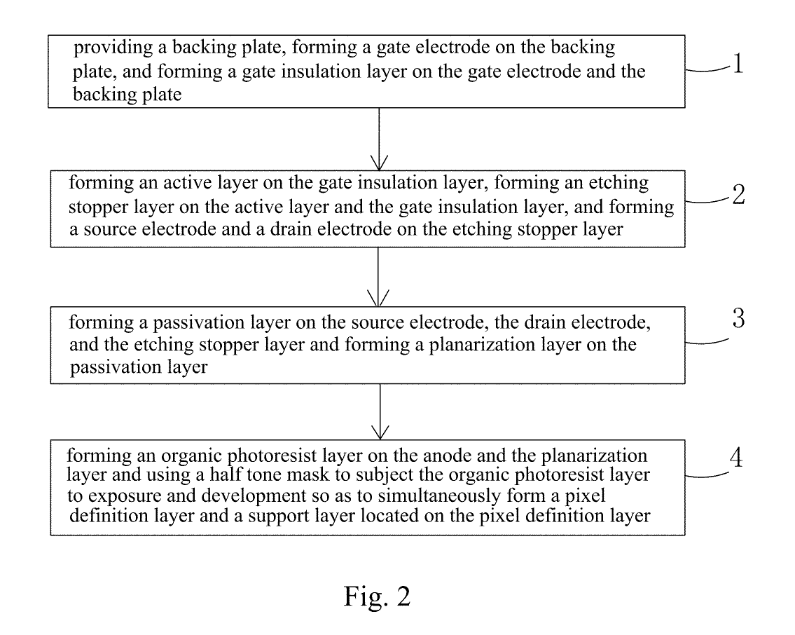

Referring to FIG. 2, firstly, the present invention provides a manufacturing method of a thin-film transistor (TFT) backplane, which comprises the following steps:

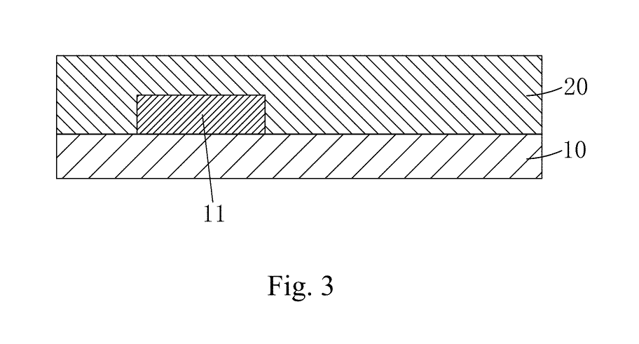

Step 1: as shown in FIG. 3, providing a backing plate 10, forming a gate electrode 11 on the backing plate 10, and forming a gate insulation layer 20 on the gate electrode 11 and the backing plate 10.

Specifically, the backing plate 10 comprises a glass substrate.

Specifically, the gate electrode 11 is formed of a material comprising one or multiple ones of molybdenum (Mo), aluminum (Al), copper (Cu), titanium (Ti), and chromium (Cr).

Specifically, the gate insulation layer 20 is formed of a material comprising one or multiple ones of silicon oxide (SiOₓ) and silicon nitride (SiNₓ).

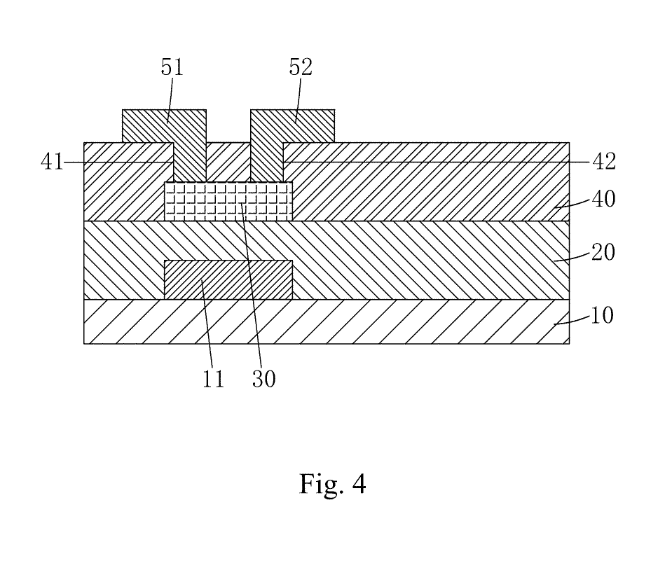

Step 2: as shown in FIG. 4, forming an active layer 30 on the gate insulation layer 20 and located above and corresponding to the gate electrode 11, forming an etching stopper layer 40 on the active layer 30 and the gate insulation layer 20, and forming a first via 41 and a second via 42 in the etching stopper layer 40 to respectively correspond to two ends of the active layer 30; and

forming a source electrode 51 and a drain electrode 52 on the etching stopper layer 40, such that the source electrode 51 and the drain electrode 52 are respectively in contact engagement with the two ends of the active layer 30 through the first via 41 and the second via 42.

Specifically, the active layer 30 is formed of a material comprising an oxide semiconductor, and preferably, the oxide semiconductor comprises indium gallium zinc oxide (IGZO).

Specifically, the etching stopper layer 40 is formed of a material comprising one or multiple ones of silicon oxide (SiOₓ) and silicon nitride (SiNₓ).

Specifically, the source electrode 51 and the drain electrode 52 are each formed of a material comprising one or multiple ones of molybdenum (Mo), aluminum (Al), copper (Cu), titanium (Ti), and chromium (Cr).

Specifically, the etching stopper layer 40 protects the active layer 30 against corrosion caused by etchant solution in an etching operation of the source electrode 51 and the drain electrode 52.

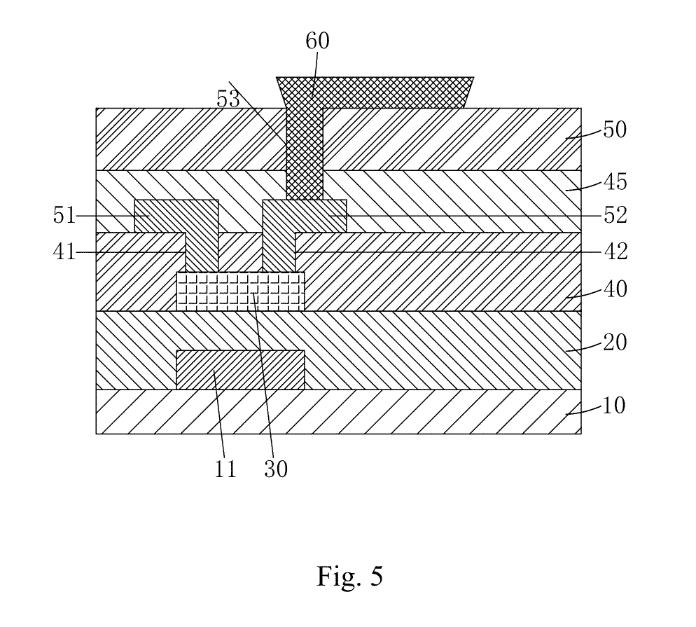

Step 3: as shown in FIG. 5, forming a passivation layer 45 on the source electrode 51, the drain electrode 52, and the etching stopper layer 40 and forming a planarization layer 50 on the passivation layer 45;

forming a third via 53 in the passivation layer 45 and the planarization layer 50 to be located above and corresponding to the drain electrode 52; and

forming an anode 60 on the planarization layer 50, such that the anode 60 is in contact engagement with the drain electrode 52 through the third via 53.

Specifically, the passivation layer 45 is formed of a material comprising one or multiple ones of silicon oxide (SiOₓ) and silicon nitride (SiNₓ).

Specifically, the planarization layer 50 comprises an organic photoresist material.

Specifically, the anode 60 comprises two transparent conductive metal oxide layers and a metal layer interposed between the two transparent conductive metal oxide layers, and preferably, the transparent conductive metal oxide layers are formed of a material comprising indium tin oxide (ITO) and the metal layer is formed of a material comprising silver.

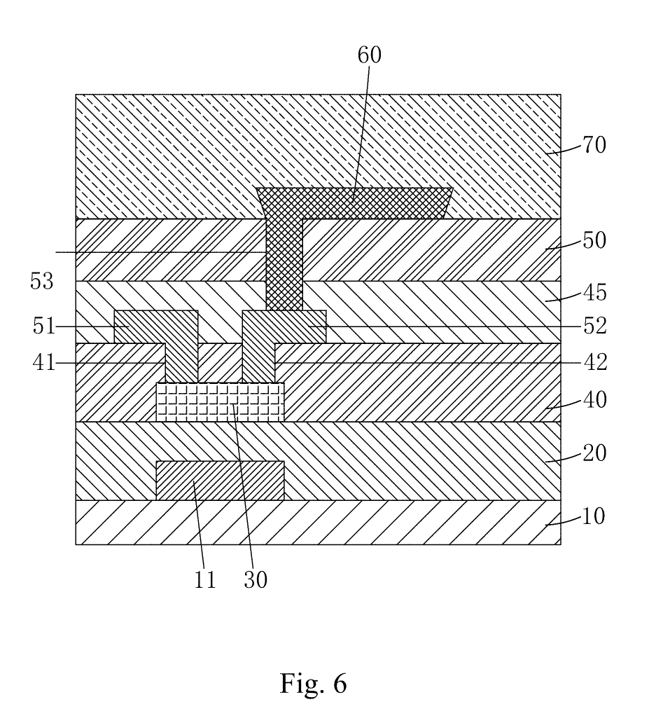

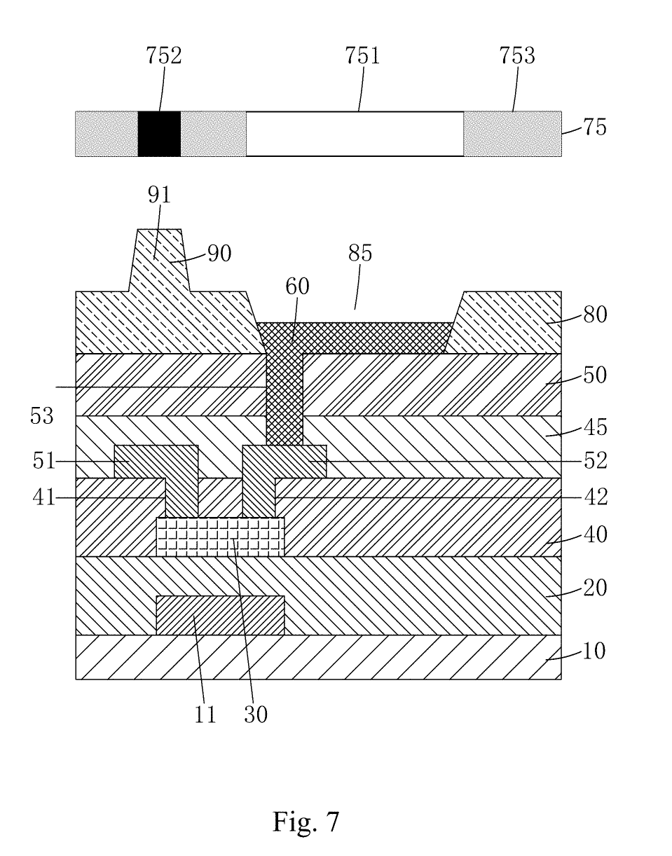

Step 4: as shown in FIGS. 6-7, forming an organic photoresist layer 70 on the anode 60 and the planarization layer 50 and using a half tone mask 75 to subject the organic photoresist layer 70 to exposure and development so as to simultaneously form a pixel definition layer 80 and a support layer 90 located on the pixel definition layer 80, wherein the pixel definition layer 80 comprises an opening 85 formed therein to be located above and corresponding to the anode 60 and the support layer 90 comprises a plurality of support members 91 that are spaced from each other.

Specifically, the opening 85 is provided for forming a light emitting pixel zone of an OLED and in subsequent operations, an emissive layer and a cathode of the OLED are formed, through vapor deposition, in the opening 85.

Specifically, the support members 91 have a configuration of a pillar shape and the support layer 90 functions to support a mask for vapor deposition in the subsequent vapor deposition operations for the emissive layer and the cathode of the OLED.

Specifically, in Step 4, the half tone mask 75 comprises a full transmission area 751 corresponding to the opening 85, a non-transmitting area 752 corresponding to the support layer 90, and a partial transmission area 753 corresponding to a portion of the pixel definition layer 80 other than the opening 85 and an area covered by the support layer 90. The full transmission area 751 has a light transmission rate that is 100%; the partial transmission area 753 has a light transmission rate that is 50%; and the non-transmission area 752 has a light transmission rate that is 0%.

The above described manufacturing method of a TFT backplane uses a half tone mask 75 that has three light transmission rates to subject an organic photoresist layer 70 to a photolithographic (exposure and development) process so that three exposure effects can be achieved with one photolithographic process to thereby simultaneously form a pixel definition layer 80, an opening 85 in the pixel definition layer 80, and a support layer 90. Compared to the known techniques, the present invention may save one mask and one round of photolithographic operation and thus may effectively reduce fixture costs and manufacturing costs. Further, structurally, the support layer 90 and the pixel definition layer 80 are a unitary structure so as to prevent detachment of the support layer 90 and thus effectively improving displaying quality of a display device. Further, the manufacturing method of the TFT backplane of the present invention can be achieved with the existing TFT operations and there is no need to modify an existing machine arrangement.

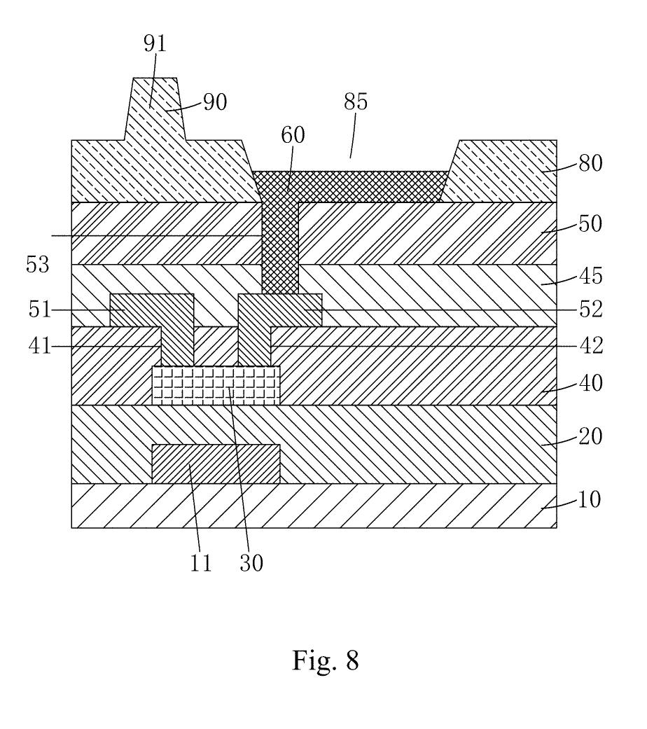

Referring to FIG. 8, based on the above-described manufacturing method of a TFT backplane, the present invention also provides a TFT backplane, which comprises: a backing plate 10, a gate electrode 11 arranged on the backing plate 10, a gate insulation layer 20 arranged on the gate electrode 11 and the backing plate 10, an active layer 30 arranged on the gate insulation layer 20 and located above and corresponding to the gate electrode 11, an etching stopper layer 40 arranged on the active layer 30 and the gate insulation layer 20, a source electrode 51 and a drain electrode 52 arranged on the etching stopper layer 40, a passivation layer 45 arranged on the source electrode 51, the drain electrode 52, and the etching stopper layer 40, a planarization layer 50 arranged on the passivation layer 45, an anode 60 arranged on the planarization layer 50, a pixel definition layer 80 arranged on the anode 60 and the planarization layer 50, and a support layer 90 arranged on the pixel definition layer 80;

wherein the etching stopper layer 40 comprises a first via 41 and a second via 42 formed therein to respectively correspond to two ends of the active layer 30 and the source electrode 51 and the drain electrode 52 are respectively in contact engagement with the two ends of the active layer 30 through the first via 41 and the second via 42;

the passivation layer 45 and the planarization layer 50 comprise a third via 53 formed therein to correspond to the drain electrode 52 and the anode 60 is in contact engagement with the drain electrode 52 through the third via 53;

the pixel definition layer 80 comprises an opening 85 formed therein and located above and corresponding to the anode 60 and the support layer 90 comprises a plurality of support members 91 that are spaced from each other; and

the pixel definition layer 80 and the support layer 90 are of a unitary structure and are formed of the same material.

Specifically, the backing plate 10 comprises a glass substrate.

Specifically, the gate electrode 11, the source electrode 51, and the drain electrode 52 are each formed of a material comprising one or multiple ones of molybdenum (Mo), aluminum (Al), copper (Cu), titanium (Ti), and chromium (Cr).

Specifically, the gate insulation layer 20, the etching stopper layer 40, and the passivation layer 45 are each formed of a material comprising one or multiple ones of silicon oxide (SiOₓ) and silicon nitride (SiNₓ).

Specifically, the active layer 30 is formed of a material comprising an oxide semiconductor, and preferably, the oxide semiconductor comprises indium gallium zinc oxide (IGZO).

Specifically, the planarization layer 50 comprises an organic photoresist material.

Specifically, the anode 60 comprising the two transparent conductive metal oxide layers and a metal layer interposed between the two transparent conductive metal oxide layers; and preferably, the transparent conductive metal oxide layers are formed of a material comprising indium tin oxide (ITO) and the metal layer comprising a material of silver.

Specifically, the support members 91 have a configuration of a pillar shape.

In the above-described TFT backplane, the pixel definition layer 80 and the support layer 90 are formed in the same process so that the manufacturing process is simple and the manufacturing cost is low and since the pixel definition layer 80 and the support layer 90 are of a unitary structure, an issue of detachment of the support layer 90 can be eliminated thereby effectively improving displaying quality of a display device.

In summary, the present invention provides a TFT backplane and a manufacturing method thereof. The manufacturing method of the TFT backplane according to the present invention uses a half tone mask that has three light transmission rates to subject an organic photoresist layer to a photolithographic process so that three exposure effects can be achieved with one photolithographic process to thereby simultaneously form a pixel definition layer, an opening in the pixel definition layer, and a support layer. Compared to the known techniques, the present invention may save one mask and one round of photolithographic operation and thus may effectively reduce fixture costs and manufacturing costs. Further, structurally, the support layer and the pixel definition layer are a unitary structure so as to prevent detachment of the support layer and thus effectively improving displaying quality of a display device. The TFT backplane according to the present invention is such that a pixel definition layer and a support layer are formed in the same process so that the manufacturing process is simple and the manufacturing cost is low and since the pixel definition layer and the support layer are of a unitary structure, an issue of detachment of the support layer can be eliminated thereby effectively improving displaying quality of a display device.

Based on the description given above, those having ordinary skills in the art may easily contemplate various changes and modifications of he technical solution and the technical ideas of the present invention. All these changes and modifications are considered belonging to the protection scope of the present invention as defined in the appended claims.

What is claimed is:

1. A manufacturing method of a thin-film transistor (TFT) backplane, comprising the following steps:
Step 1: providing a backing plate, forming a gate electrode on the backing plate, and forming a gate insulation layer on the gate electrode and the backing plate;
Step 2: forming an active layer on the gate insulation layer and located above and corresponding to the gate electrode, forming an etching stopper layer on the active layer and the gate insulation layer, and forming a first via and a second via in the etching stopper layer to respectively correspond to two ends of the active layer; and
forming a source electrode and a drain electrode on the etching stopper layer, such that the source electrode and the drain electrode are respectively in contact engagement with the two ends of the active layer through the first via and the second via;
Step 3: forming a passivation layer on the source electrode, the drain electrode, and the etching stopper layer and forming a planarization layer on the passivation layer;
forming a third via in the passivation layer and the planarization layer to be located above and corresponding to the drain electrode; and
forming an anode on the planarization layer, such that the anode is in contact engagement with the drain electrode through the third via; and
Step 4: forming an organic photoresist layer on the anode and the planarization layer and using a half tone mask to subject the organic photoresist layer to exposure and development so as to simultaneously form a pixel definition layer and a support layer located on the pixel definition layer, wherein the pixel definition layer comprises an opening formed therein to be located above and corresponding to the anode and the support layer comprises a plurality of support members that are spaced from each other.

2. The manufacturing method of the TFT backplane as claimed in claim 1, wherein in Step 4, the half tone mask comprises a full transmission area corresponding to the opening, a non-transmitting area corresponding to the support layer, and a partial transmission area corresponding to a portion of the pixel definition layer other than the opening and an area covered by the support layer.

3. The manufacturing method of the TFT backplane as claimed in claim 2, wherein the full transmission area has a light transmission rate of 100%; the partial transmission area has a light transmission rate of 50%; and the non-transmission area has a light transmission rate of 0%.

4. The manufacturing method of the TFT backplane as claimed in claim 1, wherein the active layer is formed of a material comprising an oxide semiconductor.

5. The manufacturing method of the TFT backplane as claimed in claim 4, wherein the oxide semiconductor comprises indium gallium zinc oxide.

6. The manufacturing method of the TFT backplane as claimed in claim 1, wherein the support members have a configuration of a pillar shape.

7. A thin-film transistor (TFT) backplane, comprising: a backing plate, a gate electrode arranged on the backing plate, a gate insulation layer arranged on the gate electrode and the backing plate, an active layer arranged on the gate insulation layer and located above and corresponding to the gate electrode, an etching stopper layer arranged on the active layer and the gate insulation layer, a source electrode and a drain electrode arranged on the etching stopper layer, a passivation layer arranged on the source electrode, the drain electrode, and the etching stopper layer, a planarization layer arranged on the passivation layer, an anode arranged on the planarization layer, a pixel definition layer arranged on the anode and the planarization layer, and a support layer arranged on the pixel definition layer;
wherein the etching stopper layer comprises a first via and a second via formed therein to respectively correspond to two ends of the active layer and the source electrode and the drain electrode are respectively in contact engagement with the two ends of the active layer through the first via and the second via;
the passivation layer and the planarization layer comprise a third via formed therein to correspond to the drain electrode and the anode is in contact engagement with the drain electrode through the third via;
the pixel definition layer comprises an opening formed therein and located above and corresponding to the anode and the support layer comprises a plurality of support members that are spaced from each other; and
the pixel definition layer and the support layer are of a unitary structure and are formed of the same material.

8. The TFT backplane as claimed in claim 7, wherein the active layer is formed of a material comprising an oxide semiconductor.

9. The TFT backplane as claimed in claim 8, wherein the oxide semiconductor comprises indium gallium zinc oxide.

10. The TFT backplane as claimed in claim 7, wherein the support members have a configuration of a pillar shape.

11. A manufacturing method of a thin-film transistor (TFT) backplane, comprising the following steps:
Step 1: providing a backing plate, forming a gate electrode on the backing plate, and forming a gate insulation layer on the gate electrode and the backing plate;
Step 2: forming an active layer on the gate insulation layer and located above and corresponding to the gate electrode, forming an etching stopper layer on the active layer and the gate insulation layer, and forming a first via and a second via in the etching stopper layer to respectively correspond to two ends of the active layer; and
forming a source electrode and a drain electrode on the etching stopper layer, such that the source electrode and the drain electrode are respectively in contact engagement with the two ends of the active layer through the first via and the second via;
Step 3: forming a passivation layer on the source electrode, the drain electrode, and the etching stopper layer and forming a planarization layer on the passivation layer;
forming a third via in the passivation layer and the planarization layer to be located above and corresponding to the drain electrode; and
forming an anode on the planarization layer, such that the anode is in contact engagement with the drain electrode through the third via; and
Step 4: forming an organic photoresist layer on the anode and the planarization layer and using a half tone mask to subject the organic photoresist layer to exposure and development so as to simultaneously form a pixel definition layer and a support layer located on the pixel definition layer, wherein the pixel definition layer comprises an opening formed therein to be located above and corresponding to the anode and the support layer comprises a plurality of support members that are spaced from each other;
wherein the active layer is formed of a material comprising an oxide semiconductor; and
wherein the support members have a configuration of a pillar shape.

12. The manufacturing method of the TFT backplane as claimed in claim 11, wherein in Step 4, the half tone mask comprises a full transmission area corresponding to the opening, a non-transmitting area corresponding to the support layer, and a partial transmission area corresponding to a portion of the pixel definition layer other than the opening and an area covered by the support layer.

13. The manufacturing method of the TFT backplane as claimed in claim 12, wherein the full transmission area has a light transmission rate of 100%; the partial transmission area has a light transmission rate of 50%; and the non-transmission area has a light transmission rate of 0%.

14. The manufacturing method of the TFT backplane as claimed in claim 11, wherein the oxide semiconductor comprises indium gallium zinc oxide.
